(19) United States
(12) Patent Application Publication
(10) Pub. No.: US 2008/0136038 A1
(43) Pub. Date: Jun. 12, 2008

(54) INTEGRATED CIRCUITS WITH CONDUCTIVE FEATURES IN THROUGH HOLES PASSING THROUGH OTHER CONDUCTIVE FEATURES AND THROUGH A SEMICONDUCTOR SUBSTRATE

(76) Inventors: Sergey Savastiouk, San Jose, CA (US); Valentin Kosenko, Palo Alto, CA (US); James J. Roman, Sunnyvale, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/567,494

(22) Filed: Dec. 6, 2006

(51) Int. Cl. H01L 23/535; H01L 21/768

(52) U.S. Cl. 257/774; 438/639; 257/E21.577; 257/E23.168

(57) ABSTRACT

A backside contact pad is formed in an integrated circuit, possibly designed initially with just top side contact pads (150C), by forming an opening (220) through a top side contact pad (150C) and the semiconductor substrate (110). Conductive material (520, 540, 1110, 1130) is formed in the opening and in contact with the top side pad. The conductive material also provides a backside contact pad (1310). Other embodiments are also provided.

### BACKGROUND OF THE INVENTION

The present invention relates to integrated circuits, and more particularly to integrated circuits with conductive features in through holes in semiconductor substrates.

In a typical integrated circuit, various circuit elements are manufactured in and/or above a semiconductor substrate. Contact pads are provided above the substrate to connect the circuit elements to external circuitry (e.g. to another integrated circuit, a printed wiring board, etc.). Contact pads can also be provided at the bottom of the substrate to reduce the total lateral area taken by the pads, and/or redistribute the pads and possibly reduce the area of the integrated circuit, and/or provide shorter electrical paths to the circuit elements in the integrated circuit, and/or to adapt the integrated circuit to a particular package (e.g. in vertical integration). The contact pads at the bottom can be provided by conductive features formed in through holes in the substrate. See for example U.S. Pat. No. 5,767,001 issued Jun. 16, 1998 to Bertagnolli et al.

### SUMMARY

The present invention provides new integrated circuits and fabrication methods for electrical contacts (such as contact pads) to be located at the bottom of the semiconductor substrate. The electrical contacts can be provided by conductive features in through holes in the substrate. In some embodiments, the through holes pass through other conductive features, e.g. top side contact pads. The backside contacts can thus be made under the top side contact pads, to facilitate the contact pad redistribution in integrated circuits originally designed to have only the top side contact pads.

The invention is not limited to such embodiments. The invention is defined by the appended claims, which are incorporated into this section by reference.

### BRIEF DESCRIPTION OF THE DRAWINGS

FIG. 1A shows a vertical cross section of an integrated circuit in the process of fabrication according to some embodiments of the present invention.

FIG. 1B is a top view of the structure of FIG. 1A.

FIG. 2 shows a vertical cross section of an integrated circuit in the process of fabrication according to some embodiments of the present invention.

FIG. 3 is a top view of an integrated circuit in the process of fabrication according to some embodiments of the present invention.

FIGS. 4A, 4B, 5, 6, 7A, 7B, 8-16 show vertical cross sections of structures comprising integrated circuits in the process or at the end of fabrication according to some embodiments of the present invention.

### DESCRIPTION OF SOME EMBODIMENTS

The embodiments described in this section illustrate but do not limit the invention. The invention is not limited to specific materials, dimensions, structural features, or other particulars except as defined by the appended claims.

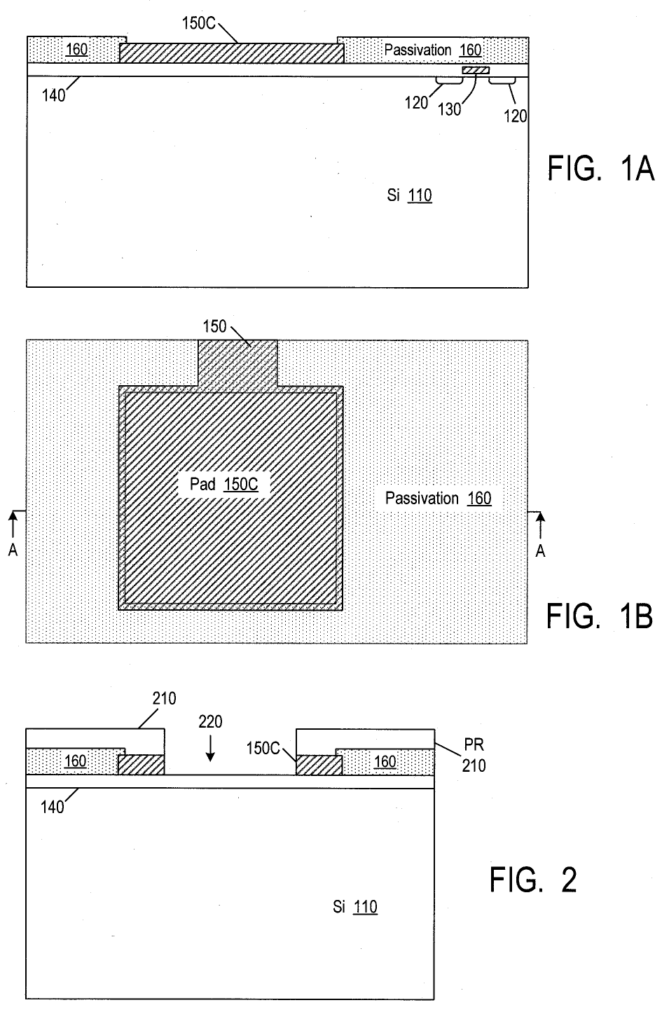

FIGS. 1A, 1B illustrate an integrated circuit at an intermediate stage of fabrication according to some embodiments of the present invention. FIG. 1A shows a vertical cross section which is marked A-A in FIG. 1B. FIG. 1B shows the top view. The integrated circuit is shown before formation of contact pads at the bottom. Semiconductor substrate 110 may be monocrystalline silicon or some other material. The substrate may include transistor active areas at the top surface and elsewhere, including for example source/drain regions 120 of a MOS transistor having a gate 130 positioned above the substrate 110 and insulated from the substrate. The transistors are not shown in the subsequent figures. Layer 140, containing one or more dielectric and/or other layers, and possibly providing other circuit elements, has been formed on substrate 110. A conductive layer 150 has been deposited and patterned to provide contact pads 150C. Contact pads 150C may be connected to other elements of the integrated circuit, such as elements 120, 130, by single or multiple layers of wiring (not shown) using known techniques. Dielectric passivation layer 160 has been deposited over the semiconductor wafer and patterned to expose the contact pads.

The invention is not limited to circuits with transistors.

The embodiment being described is suitable for modifying the manufacturing process to provide backside (bottom-side) contact pads in an integrated circuit originally designed without such pads. For example, the integrated circuit could be designed to provide contact pads (such as pads 150C) only at the top. Then pads 150C can be electrically contacted from the bottom as described below. However, the invention is not limited to such embodiments. For example, layer 150 may be an intermediate conductive layer to be connected to backside contact pads and, possibly, to contact pads at the top.

For the sake of illustration, in some embodiments, substrate 110 is 150 mm thick monocrystalline silicon. Layer 150 is metal, and can be formed by depositing a 10 nm layer of titanium (Ti), then a 20 nm layer of titanium nitride (TiN), then a 1 μm layer of aluminum-copper (AlCu), then a 25 nm layer of TiN. Layer 140 can be a combination of a 600 nm layer of field oxide (silicon dioxide used to insulate active areas in substrate 110 from each other) and a 650 nm layer of BPSG (borophosphosilicate glass). Thus, in some embodiments, the only materials between substrate 110 and contact pads 150C are dielectric, but this is not necessary. Layer 160 may consist of a 600 nm bottom layer of silicon dioxide and a 600 nm layer of silicon nitride.

A masking layer 210 (FIG. 2), e.g. photoresist, is deposited and patterned to define an opening over a center portion of each contact pad 150C. In some embodiments, the opening is circular, and a suitable diameter is 70 μm, but other geometries and dimensions are possible. (FIGS. 2 and 4A-16 show vertical cross sections by the same sectional plane as FIG. 1A.)

Metal 150 is etched in the mask openings to form an opening 220 through the center portion of each contact pad 150C. This is done by a wet etch in some embodiments.

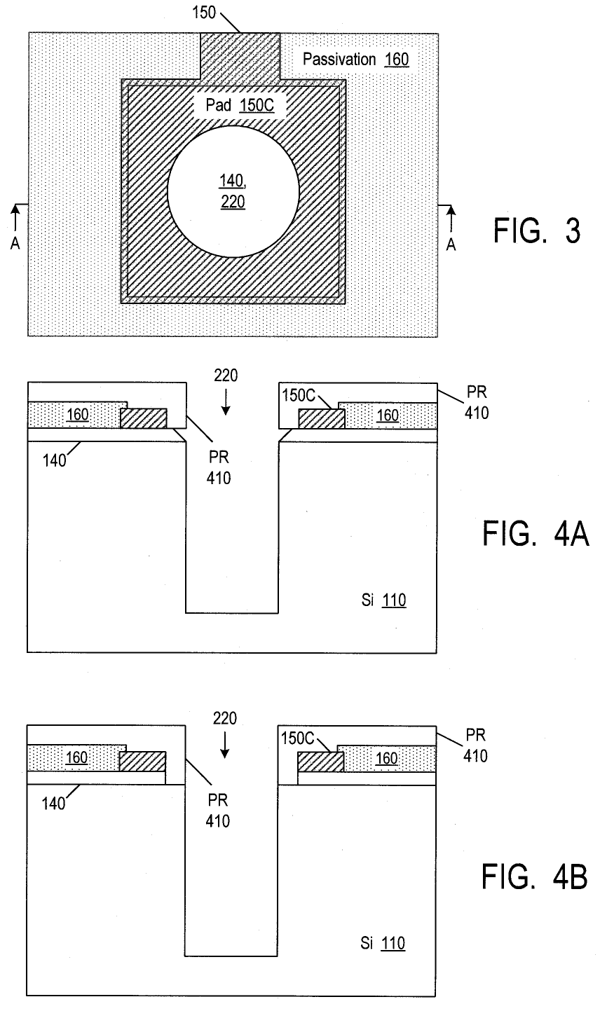

Resist 210 is removed. See FIG. 3 (top view). Another optional masking layer 410 (FIG. 4A), e.g. photoresist, is deposited and patterned to completely cover the wafer except for the center portions of openings 220. Metal 150C is completely covered by mask 410. In some embodiments, the exposed center portions of openings 220 are circular, of a 60 μm diameter each.

Layer 140 and substrate 110 are etched through the mask openings to extend the openings 220 into substrate 110. In some embodiments, layer 140 can be etched by a wet etch process, and substrate 110 by deep reactive ion etching (DRIE). In an exemplary embodiment, each opening 220 extends 200˜250 μm into substrate 110.

In another variation, oxide 140 is etched through the openings in mask 210 at the stage of FIG. 2, to expose silicon 110. Then mask 410 is formed for the silicon etch as described above and shown in FIG. 4B. Mask 410 advantageously protects the oxide 140 at the edges of openings 220.

In other embodiments (not shown), mask 410 is omitted, and the openings 220 are extended by DRIE into silicon with mask 210 protecting the rest of the wafer. In such embodiments, contact pads 150C are exposed at the openings' edges during the plasma-assisted DRIE etch, which is believed to be undesirable in some embodiments as the plasma may induce electrical currents through contact pads 150C, and these currents may damage other circuitry (e.g. transistors) connected to the contact pads.

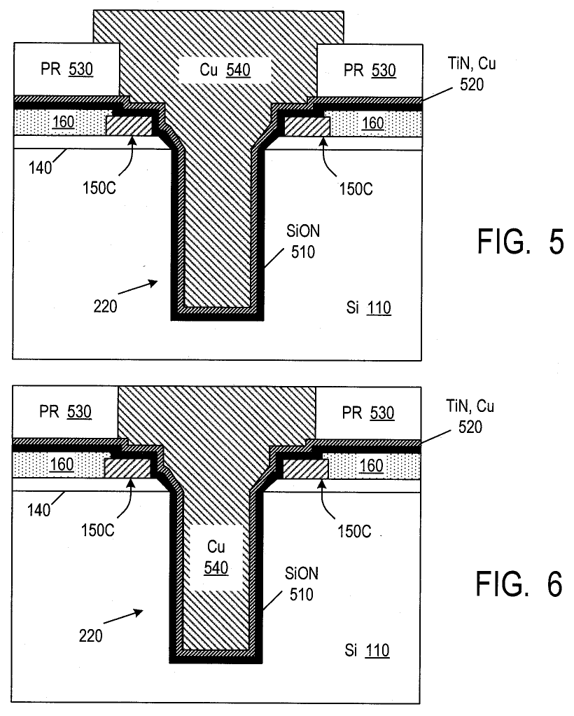

If mask 410 was used, it is removed (see FIG. 5). An optional dielectric liner 510, e.g. silicon oxynitride or a silicon oxide layer deposited from TEOS, is formed on the wafer. Liner 510 covers the surfaces of openings 220, including the edges of contact pads 150C at the openings. Then a conductor is formed in the openings. In some embodiments, this is done as follows. A thin layer 520 is deposited which includes a bottom barrier layer of titanium tungsten (TiW) and a seed layer of copper (Cu). Then a masking layer 530, e.g. dry film negative photoresist, is formed on the wafer and patterned to expose the openings 220 and possibly adjacent areas. Copper 540 is electroplated on the exposed portions of layer 520. In some embodiments, copper 540 fills the openings 220 and extends up above the resist 530. Voids can be present in copper 540 however, as known in the art. Layers 520, 540 are insulated from layer 150 and any other conductive features that may be present in the wafer.

Copper 540 is polished by chemical mechanical processing (CMP). See FIG. 6. The CMP stops on resist 530.

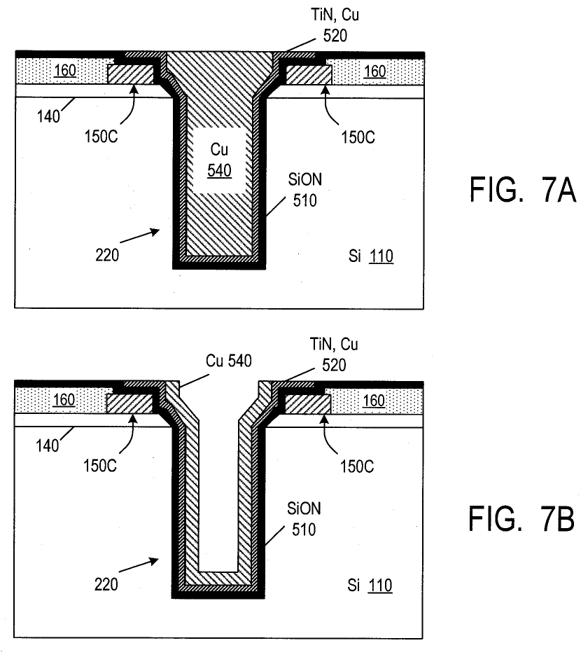

Resist 530 is removed (FIG. 7A), and CMP is performed to remove layers 540, 520 above the oxynitride 510. The wafer top surface is planar after this step. The openings 220 are blocked on the top by layers 540, 520, which are insulated from every other conductive feature in the wafer.

FIG. 7B illustrates another embodiment. Here copper 540 was deposited so as not to fill the openings 220 at the stage of FIG. 5 but to cover the openings' sidewalls. The result is an open void at the top of the copper layer. Advantageously, there is less likely to be a closed void (enclosed on all sides by the copper). Closed voids may trap harmful materials in the electroplating solution. In the embodiment of FIG. 7B, the void may be closed by other subsequently deposited layers, but harmful materials can be at least partially removed before the void is closed. Also, the structure of FIG. 7B provides more room for copper 540 to expand when heated (copper has a higher thermal expansion coefficient than silicon, so the expansion of silicon 110 may be insufficient to avoid thermal stresses in copper 540). The subsequent fabrication steps are shown for the embodiment of FIG. 7A. The same steps are suitable for FIG. 7B.

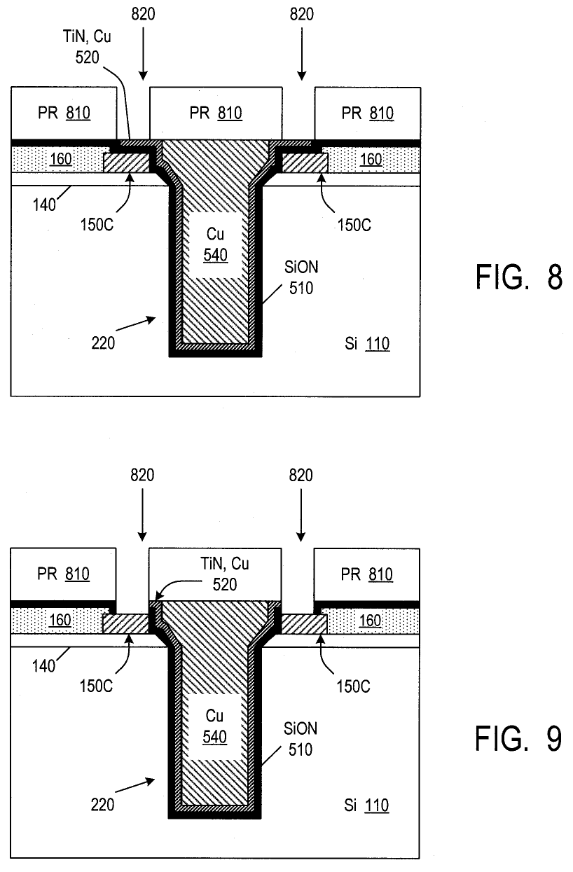

A masking layer 810 (FIG. 8), e.g. dry film negative photoresist, is formed over the wafer and patterned to cover the openings 220. In some embodiments, mask 810 completely covers the copper 540 in each opening. Mask 810 has an opening 820 over each contact pad 150C. In some embodiments, each opening 820 completely surrounds the respective opening 220, but this is not necessary. In FIG. 8, mask 810 overlies and protects the passivation 160.

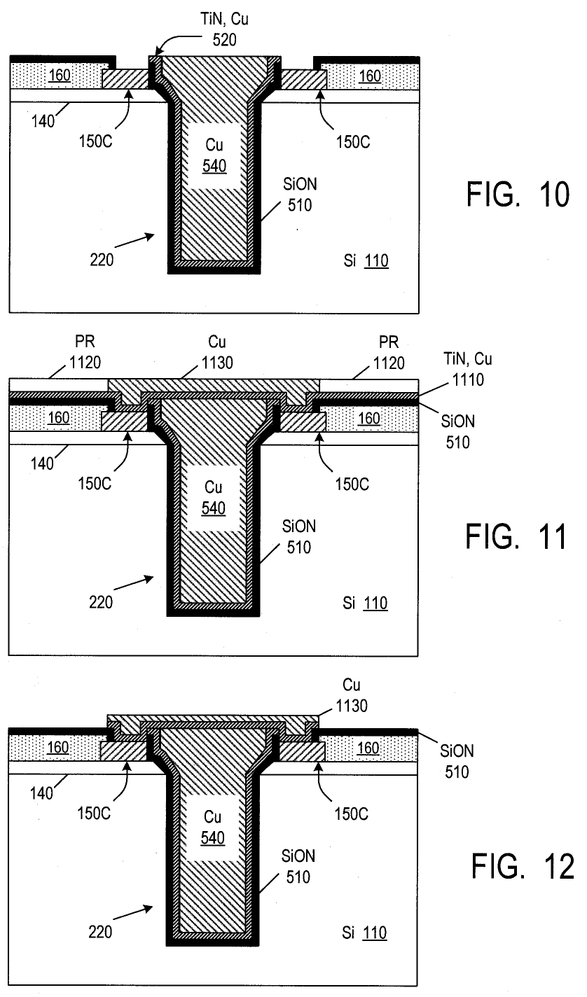

TiN/Cu layer 520 is etched in each opening 820 (by a wet etch for example) to expose SiON 510 (FIG. 9). Then contact pads 150C are exposed by a SiON etch. For example, SiON 510 can be etched through openings 820 by an isotropic dry etch. Then resist 810 is removed. The resulting structure is shown in FIG. 10.

Copper 540 and TiN/Cu 520 are then connected to contact pads 150C. In the example of FIG. 11, a conductive layer 1110 is deposited on copper 540 and the exposed portions of contact pads 150C. Layer 1110 includes a bottom layer of titanium tungsten (TiW) and a seed layer of copper. Then a mask layer 1120, e.g. photoresist, is formed to cover the whole wafer except for the areas over, and/or adjacent to, the openings 220 where additional copper 1130 is to be electroplated. Copper 1130 is electroplated on seed layer 1110 exposed in these areas, to increase the contact height at the top. Copper 1130 is polished by CMP. The CMP stops on resist 1120. The resist is removed, and the layers 1130, 1110 are etched (by a wet etch for example) until the layer 1110 is removed in the areas not covered by copper 1130 (FIG. 12). Some of copper 1130 remains due to a larger initial thickness of this layer.

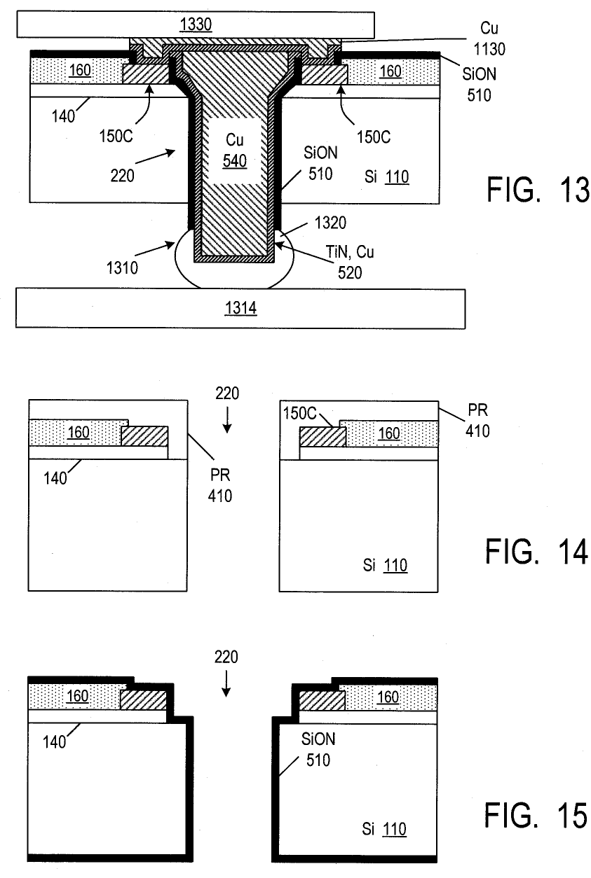

As shown in FIG. 13, the wafer backside (bottom side) is then processed to expose the conductive layers 520 and/or 540 on the bottom. The exposed layers form a backside contact 1310 which can be attached to an external structure 1314 (e.g. a printed wiring board, another semiconductor integrated circuit, or some other structure, known or to be invented). See e.g. U.S. Pat. No. 7,060,601 issued Jun. 13, 2006 to Savastiouk et al., and U.S. Pat. No. 7,049,170 issued May 23, 2006 to Savastiouk et al., both incorporated herein by reference. Many techniques can be used to form the backside contacts. In some embodiments, substrate 110 is mechanically ground on the bottom to a thickness of about 250 μm. Then a plasma etch of the wafer backside is performed at atmospheric pressure, with CF₄ as an etchant. A suitable process is Atmospheric Downstream Plasma (“ADP”) provided by Tru-Si Technologies, Inc. of Sunnyvale, Calif. See for example, U.S. Pat. No. 7,001,825 issued Feb. 21, 2006 to Halahan et al., U.S. Pat. No. 6,958,285 issued Oct. 25, 2005 to Siniaguine, and U.S. Pat. No. 6,693,361 issued Feb. 17, 2004 to Siniaguine et al., all incorporated herein by reference. This process will etch both silicon 110 and SiON 510 to expose the barrier/seed layer 520. In some embodiments, the etch is conducted until the bottom surface of silicon 110 is about 30 μm above the initial position of the bottom surface of opening 220. SiON 510 is etched slower than silicon 110, so SiON 510 protrudes down below the silicon. An additional plasma etch with SF₆ can be conducted to reduce the thickness of substrate 110 by another 20 μm. Advantageously, both etches are blanked etches, no photolithography is needed. The invention is not limited to such embodiments however.

Contacts 1310 can be attached to a contact (not shown) of another structure 1314, directly or with bond wires, using solder 1320, or thermocompression, or a suitable adhesive, or by other methods, known or to be invented. Protruding SiON 510 helps insulate the solder from silicon 110. Copper 1130 can be attached to a contact (not shown) of another structure 1330 (e.g. a printed wiring board, another semiconductor integrated circuit, or some other structure, known or to be invented) using such methods.

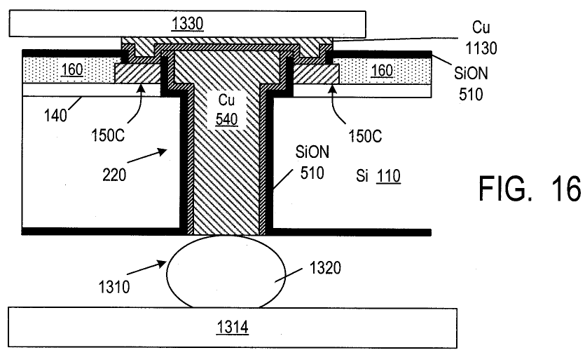

FIG. 14 shows another embodiment, at the stage of FIG. 4A or 4B. In FIG. 14, the substrate 110 is thinned (e.g. ground and/or etched to its final thickness) before the extension of openings 220 into the substrate. The openings 220 are extended to become through holes at the stage of FIG. 4A or 4B. Then dielectric 510 (FIG. 15) is formed on the top and bottom surfaces of the wafer and over the openings' sidewalls. The remaining fabrication steps can be essentially as in FIGS. 5-13. FIG. 16 shows the final structure in some embodiments using the process of FIG. 4B. Dielectric 510 insulates silicon 110 from solder 1320 on the bottom. Other processes described in connection with FIGS. 5-13 can also be used with the through holes 220 of FIG. 14.

The invention is not limited to the embodiments described above except as defined by the appended claims. For example, various materials can be used instead of copper, silicon, or other materials described above. Dielectric 510 can be omitted. The invention is not limited to electroplating or other processes described above except as defined by the appended claims. Multiple conductive layers insulated from each other can be formed in each opening 220, as described in the aforementioned U.S. Pat. No. 7,001,825. In some embodiments, some or all of the copper contacts 540 are not contacted from the top of the wafer. Layers 1110 and/or 1130 (FIGS. 11, 13, 16) can be patterned to connect contact pads 150C to other contact pads or features of the integrated circuit. In some embodiments, mask 530 is omitted (FIG. 5), copper 540 is electroplated on the whole wafer, and layers 540, 520 are polished by CMP to expose SiON 510. The backside etch of FIG. 13 can occur before or after the wafer attachment to structure 1330. Additional dielectric can be used to cover the wafer's top side, possibly before the backside etch of FIG. 13.

In some embodiments, a method for manufacturing an integrated circuit comprises: (a) obtaining a structure comprising a semiconductor substrate (e.g. substrate 110) and one or more first conductive features (e.g. pads 150C in FIG. 1A); (b) forming one or more through holes (e.g. through holes 220 formed at the stage of FIG. 13 or 14) passing through the one or more first conductive features and through the semiconductor substrate; (c) forming one or more second conductive features (e.g. layers 520, 540, 1110, 1130 in FIGS. 11-13, 16) at least partially located in the one or more through holes, each second conductive feature contacting at least one first conductive feature.

In some embodiments, operation (b) comprises: before operation (c), forming one or more openings passing through the one or more first conductive features and through a top portion of the semiconductor substrate but not through a bottom portion of the semiconductor substrate (e.g. openings 220 in FIG. 4A or 4B); and after operation (c), removing a bottom portion of the structure, the bottom portion of the structure including a bottom portion of the semiconductor substrate, to create the one or more through holes through the semiconductor substrate at a location of the one or more openings and provide the one or more electrical contacts (e.g. 1310 in FIG. 13) at the bottom of the structure.

Some embodiments further comprise, before operation (c), forming a dielectric (e.g. 510) over a surface of each said opening (as in FIG. 5) or each said through hole (e.g. FIG. 15); wherein operation (c) comprises: forming a first portion of each second conductive feature (e.g. layers 520, 540), each first portion being at least partially located in one of the one or more openings or through holes and being insulated from the first conductive features by at least the dielectric; (c2) removing at least a portion of the dielectric over one or more areas of one or more of the first conductive features (e.g. as in FIG. 10); and (c3) forming a second portion of each second conductive feature (e.g. 1110, 1130) to connect the first portion of the second conductive feature to at least one first conductive feature.

Some embodiments provide an integrated circuit comprising: a semiconductor substrate (e.g. 110); one or more first conductive features (e.g. 150C in FIG. 13) overlying the semiconductor substrate; one or more through-holes (e.g. 220 in FIG. 13) passing through the one or more first conductive features and the semiconductor substrate, wherein each first conductive feature has an edge at a sidewall of one of said one or more through-holes (150C has an edge surrounding the through-hole 220 in FIGS. 13, 16); one or more second conductive features (e.g. layers 520, 540, 1110, 1130 in FIGS. 13, 16), each second conductive feature at least partially located in one of said through-holes and contacting a first conductive feature having an edge at the sidewall of said one of said one or more through-holes, each second conductive feature providing an electrical contact (e.g. 1310) for contacting the integrated circuit at the bottom of the integrated circuit.

In some embodiments, the integrated circuit further comprises dielectric (e.g. 510) separating each said edge at the sidewall of said one of said one or more through-holes from the second conductive feature at least partially located in said one of said one or more through-holes.

Other embodiments and variations are within the scope of the invention, as defined by the appended claims.

1. A method for manufacturing an integrated circuit, the method comprising:
(a) obtaining a structure comprising a semiconductor substrate and one or more first conductive features overlying the semiconductor substrate;
(b) forming one or more through holes passing through the one or more first conductive features and through the semiconductor substrate, wherein forming the one or more through holes comprises removing a portion of each first conductive feature; and
(c) forming one or more second conductive features at least partially located in the one or more through holes, each second conductive feature contacting at least one first conductive feature and providing an electrical contact at the bottom of the structure.

2. The method of claim 1 wherein operation (b) comprises:
(b1) before operation (c), forming one or more openings passing through the one or more first conductive features and through a top portion of the semiconductor substrate but not through a bottom portion of the semiconductor substrate; and
(b2) after operation (c), removing a bottom portion of the structure, the bottom portion of the structure including the bottom portion of the semiconductor substrate, to create the one or more through holes through the semiconductor substrate at a location of the one or more openings and provide the one or more electrical contacts at the bottom of the structure.

3. The method of claim 2 further comprising, before operation (c), forming a dielectric over a surface of each said opening;
wherein operation (c) comprises:
(c1) forming a first portion of each second conductive feature, each first portion being at least partially located in one of the one or more openings and being insulated from the first conductive features by at least the dielectric;
(c2) removing at least a portion of the dielectric over one or more areas of one or more of the first conductive features; and
(c3) forming a second portion of each second conductive feature to connect the first portion of the second conductive feature to at least one first conductive feature.

4. The method of claim 3 wherein all of the semiconductor substrate is located below each second portion.

5. The method of claim 1 wherein operation (b) is performed before operation (c).

6. The method of claim 5 further comprising, before operation (c), forming a dielectric over a surface of each said through hole;
wherein operation (c) comprises:
(c1) forming a first portion of each second conductive feature, each first portion being at least partially located in one of the one or more through holes and being insulated from the first conductive features by at least the dielectric;
(c2) removing at least a portion of the dielectric over one or more areas of one or more of the first conductive features; and
(c3) forming a second portion of each second conductive feature to connect the first portion of the second conductive feature to at least one first conductive feature.

7. The method of claim 6 wherein all of the semiconductor substrate is located below each second portion.

8. The method of claim 1 further comprising attaching at least one said electrical contact to a contact external to the integrated circuit.

9. An integrated circuit comprising:
a semiconductor substrate;
one or more first conductive features overlying the semiconductor substrate;
one or more through-holes passing through the one or more first conductive features and the semiconductor substrate, wherein each first conductive feature has an edge at a sidewall of one of said one or more through-holes;
one or more second conductive features, each second conductive feature at least partially located in one of said through-holes and contacting a first conductive feature having an edge at the sidewall of said one of said one or more through-holes, each second conductive feature providing an electrical contact for contacting the integrated circuit at a bottom of the integrated circuit.

10. The integrated circuit of claim 9 wherein each said edge at the sidewall of one of said through-holes laterally surrounds said one of said one or more through-holes.

11. The integrated circuit of claim 9 further comprising dielectric separating each said edge at the sidewall of said one of said one or more through-holes from the second conductive feature at least partially located in said one of said one or more through-holes.

12. The integrated circuit of claim 9 wherein the electrical contact is attached to a conductive element external to the integrated circuit.

13. An integrated circuit comprising:
a semiconductor substrate;
one or more first conductive features overlying the semiconductor substrate;
one or more through-holes passing through the one or more first conductive features and the semiconductor substrate, wherein each said through-hole is laterally surrounded by one of said one or more first conductive features;
one or more second conductive features, each second conductive feature at least partially located in one of said through-holes and contacting a first conductive feature laterally surrounding said one of said through-holes.

14. The integrated circuit of claim 13 further comprising dielectric separating each said edge at the sidewall of said one of said one or more through-holes from the second conductive feature at least partially located in said one of said one or more through-holes.
